(19) United States
(12) Patent Application Publication
(10) Pub. No.: US 2014/0332054 A1
(43) Pub. Date: Nov. 13, 2014

(54) SOLAR COLLECTOR HAVING A PIVOTABLE CONCENTRATOR ARRANGEMENT

(71) Applicant: Airlight Energy IP SA, Biasca (CH)

(72) Inventors: Gianluca Ambrosetti, Gentilino (CH); Jonathan Chambers, Prevessin-Moens (FR); Thomas Cooper, Zurich (CH); Andrea Pedretti-Rodi, Bellinzona (CH)

(73) Assignee: Airlight Energy IP SA, Biasca (CH)

(21) Appl. No.: 14/361,285

(22) PCT Filed: Nov. 22, 2012
(86) PCT No.: PCT/CH2012/000260

§ 371 Date: May 28, 2014

(30) Foreign Application Priority Data
Nov. 29, 2011 (CH) 1906/11
Dec. 1, 2011 (CH) 1910/11

(51) Int. Cl. H01L 31/052; G02B 7/183

(52) U.S. Cl. CPC H01L 31/0525; G02B 7/183
USPC 136/246; 136/259; 359/853

(57) ABSTRACT

The invention relates to a trough collector comprising a number of secondary concentrators, by which the solar radiation concentrated by the concentrator of the trough collector in a first direction transverse to the length thereof is concentrated in a second direction running along the trough collector, wherein the secondary concentrators each have a first, front reflecting wall and a second, rear reflecting wall which concentrate the radiation in the second direction, and wherein the secondary concentrators are arranged such as to be synchronously pivotable with one another, preferably about a respective pivot axis fixed with respect to the primary concentrator, such that as the position of the sun changes, the secondary concentrators can always be oriented in accordance with the incident radiation. The invention is characterised in that the first and the second reflecting wall of the secondary concentrators have different lengths in the entry region of the radiation, such that a longer reflecting wall of one secondary concentrator lies in each case next to a shorter reflecting wall of the adjacent secondary concentrator. The secondary concentrators can thereby be arranged side by side without a gap, yet remain pivotable over a range of minus 20 degrees to plus 70 degrees with respect to the primary concentrator.

The present invention relates to a trough collector according to the preamble of claim 1, a trough collector according to claim 16, as well as a secondary concentrator according to claim 16.

Trough collectors or secondary concentrators of the mentioned kind are used in solar power plants, among other places.

Efforts to cost-effectively generate solar power using photovoltaics have thus far met with failure due to the as yet unresolved disadvantages associated with this technology. By contrast, solar thermal power plants have for some time already been producing power on an industrial scale at prices close to the commercial prices common today for power generated in a conventional manner, as opposed to photovoltaics.

In solar thermal power plants, sunlight is mirrored by collectors with the help of the concentrator, and specifically focused on a location where high temperatures arise as a result. The concentrated heat can then be dissipated and used to operate thermal machines, like turbines, which in turn drive the power-producing generators. In photovoltaic power plants, solar radiation is focused on photocells, which directly generate power.

Three basic types of solar thermal power plants are in use today: Dish-Sterling systems, solar tower power plant systems and parabolic trough systems. The use of photovoltaics is being increasingly discussed in particular with regard to parabolic trough systems.

Dish-Sterling systems as small units with a range up to 50 kW per module (whether thermal or photovoltaic) have generally not gained acceptance.

Solar tower power plant systems have a central, elevated absorber (mounted on the “tower”) for the sunlight mirrored toward it by hundreds to thousands of individual mirrors, thereby concentrating the radiant energy of the sun in the absorber via the numerous mirrors or concentrators, the objective being to reach temperatures of up to 1,300° C. in this way, which is beneficial for the efficiency of downstream thermal machines (as a rule a steam or fluid turbine power plant for generating power). The “Solar two” plant in California has an output of several MW. The PS20 plant in Spain has an output of 20 MW. Solar tower power plants have to date not become very widespread either (despite the advantageously achievable high temperatures).

However, parabolic trough power plants are widespread, and have high numbers of collectors, which exhibit long concentrators with small transverse dimensions, and thus have no focal point, but rather a focal line. These linear concentrators today have a length of 20 m to 150 m, but can also be designed with a length of 200 m or more. An absorber pipe for the concentrated heat (up to about 500° C.) runs in the focal line, and transports the heat to the power plant. Possible transport mediums include thermal oil, melted salts or superheated water vapor. Photovoltaic systems can be equipped with photocells situated at the location of the focal line.

Conventional absorber pipes are fabricated with a complicated and expensive design so as to minimize heat loss as much as possible. Since the heat-transporting medium circulates inside the pipe, the solar radiation concentrated by the concentrator first heats the pipe, which then heats the medium, so that the absorber pipe, which of necessity is up to about 500° C. hot, radiates heat proportionately to its temperature. The radiation of heat via the line network for the heat-transporting medium can reach 100 W/m, and the line length in a large-scale plant can reach up to 100 km, so that heat losses over the line network are considerably important for the overall efficiency of the power plant, as is the percentage of heat lost owing to the absorber pipes.

Consequently, the absorber lines are being given an increasingly intricate design to avoid these energy losses. Widely used conventional absorber lines are designed as a metal pipe sheathed in glass, wherein a vacuum prevails between the glass and metal pipe. The metal pipe carries the heat-transporting medium on its interior, while its outer surface is provided with a coating that better absorbs irradiated light in the visible range, but has a low emission rate for wavelengths in the infrared range. The enveloping glass pipe protects the metal pipe against being cooled by the wind, and acts as an additional barrier to heat dissipation. The disadvantage here is that the enveloping glass wall also partially reflects or even absorbs incident concentrated solar radiation, causing a layer that reduces reflection to be applied to the glass.

In order to lower the laborious effort involved in cleaning such absorber lines, while also protecting the glass against mechanical damages, the absorber line can also be encased by a mechanical protective pipe (that provides little or no insulation), which even though it must be furnished with an opening for the incident sunlight, otherwise protects the absorber line quite reliably.

Such structures are complicated and correspondingly expensive, both to manufacture and maintain. Therefore, it would appear to be of increasing interest that trough collectors be provided not just for the thermal use of solar energy, but also for photovoltaic use.

The 9 SEGS parabolic trough power plants in Southern California together produce an output of approx. 350 MW. The “Nevada Solar One” power plant that went on line in 2007 has trough collectors with 182,400 curved mirrors arranged on a 140 hectare surface, and produces 65 MW. Andasol 3 in Spain has been under construction since September 2009 and is slated for startup in 2011, so that the Andasol 1 to 3 plants will have a peak output of 50 MW.

A peak efficiency of approx. 20% and average annual efficiency of roughly 15% are expected for the combined (thermal) plant (Andasol 1 to 3).

As mentioned, one essential parameter for the efficiency of a solar power plant involves the temperature of the transport medium heated by the collectors, with which the generated heat is transported away from the collector and used for conversion, e.g., into electricity: a higher efficiency can be achieve during conversion with a higher temperature. The temperature realizable in the transport medium in turn depends on the concentration of reflected sunlight by the concentrator. A concentration of 50 means that an energy density per m² is achieved in the focal area of the concentrator measuring 50 times the energy emitted by the sun on one m² of the earth's surface.

The theoretically maximum possible concentration depends on the earth-sun geometry, i.e., on the opening angle of the solar disk as observed from the earth. As follows from this opening angle of 0.27°, the theoretically maximum possible concentration factor for trough collectors lies at 213.

The mirrors are difficult to manufacture, and hence (too) expensive for industrial application, and although they approximate a parabola well in terms of their cross section, thereby generating a focal line area with the smallest diameter, even they cannot be used at present just to come anywhere close to this maximum concentration of 213. A reliably achievable concentration of approx. 50 to 60 is realistic, however, and already permits the aforementioned temperatures of up to 500° C. in the absorber pipe of a parabolic trough power plant.

The deliberations about concentration apply similarly to photovoltaic power generation, since more electricity can be generated at a higher concentration.

In order to come as close as possible to the parabolic shape of a trough collector at reasonable costs, the Applicant in WO 2010/037 243 proposed a trough collector that exhibits a pressure cell with a flexible concentrator mounted in the pressure cell. The concentrator here is varyingly curved in different areas, and thereby comes quite close to the desired parabolic shape. This makes it possible to achieve a concentration for the radiation that enables a temperature of close to 500° C. in the absorber pipe at justifiable costs, but not to again elevate the process temperature further in the absorber pipe.

For this reason, US 2010/0037953 proposes that a trough collector be equipped with secondary concentrators. As a result, the radiation concentrated by the primary concentrator of the trough collector transversely to its length is again concentrated, this time longitudinally, thereby generating a row of focal points over the length of the trough collector in which the solar radiation is more highly concentrated. In order to be able to align the secondary concentrators to reflect the position of the sun, they are configured to be synchronously pivoted relative to each other.

The depicted arrangement of secondary concentrators has a complicated design, and does not permit fully utilizing the capacity of the primary collector for different angles of inclination of the secondary concentrators, since they leave gaps open between them when in a straight position, which corresponds to unused radiation, or if not exhibiting any gaps, already collide with each other when just slightly skewed. This yields a reduced efficiency for the entire collector, since the gaps make it impossible to use the radiation on the one hand, and the secondary concentrators can only be inadequately correspondingly aligned to the position of the sun, i.e., the skew angle, given minimized gaps on the other.

Therefore, the object of the present invention is to create a trough collector with secondary concentrators having an improved efficiency.

This object is achieved by a solar collector with the characterizing features in claims 1 and 13, as well as by a secondary concentrator with the characterizing features in claim 16.

Because the pivoting range of the secondary concentrators extends from a positive angular range over the vertical and into the negative angular range, and the radiation reflected by the primary concentrator can be completely detected in all angular positions, the radiation reflected by the primary concentrator can be completely utilized at practically any time of day.

A simple design is made available for achieving the object of the present invention by having the longitudinally concentrating walls of the secondary concentrators exhibit a varying length in the area where the radiation enters, so that a longer reflecting wall of a secondary concentrator lies next to a respective shorter reflecting wall of the adjacent secondary concentrator.

The efficiency is additionally increased by arranging the secondary concentrators in several rows along the length of the primary concentrator, wherein each row of secondary concentrators is aligned to a longitudinal section of the primary concentrator allocated to it. Even though the secondary concentrators absorb less radiation in the transverse direction as a result, they can be designed with a lower acceptance angle in the longitudinal direction, which improves concentration as such, and thus elevates the efficiency of the configuration.

In terms of its effect, arranging the secondary concentrators in several rows is independent of how the secondary concentrators are designed according to the invention with respect to their ability to pivot, but synergistic for achieving an optimal efficiency.

Special embodiments of the present invention are described in greater detail in the dependent claims and based on the figures.

In the figures:

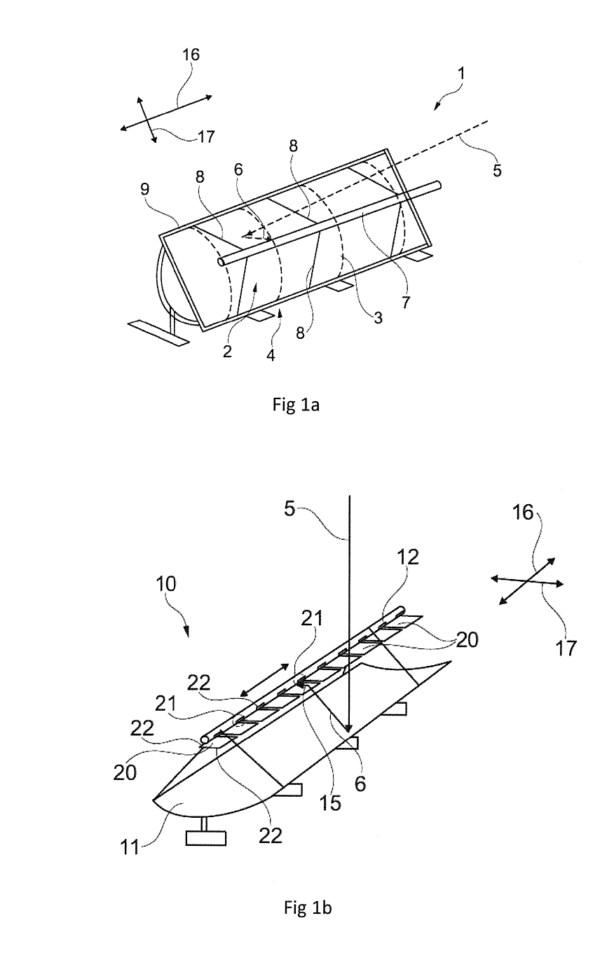

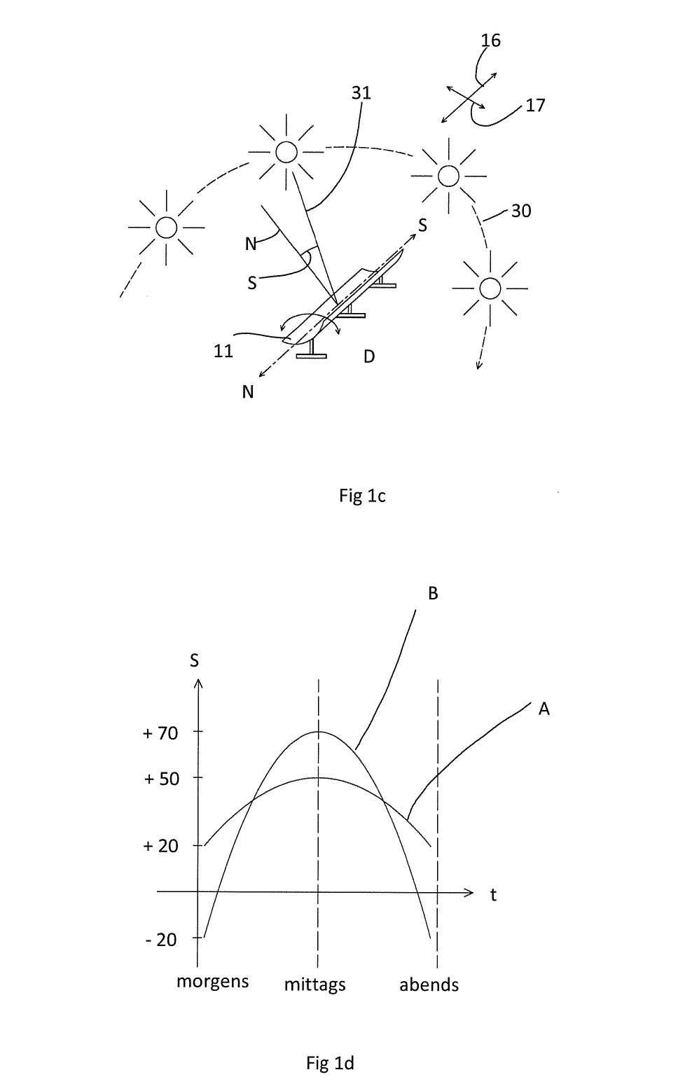

FIG. 1a shows a diagrammatic view of a trough collector according to prior art, with a pressure cell,

FIG. 1b shows a diagrammatic view of a trough collector according to FIG. 1a, which exhibits secondary concentrators,

FIG. 1c shows a diagrammatic view depicting the changing angle of incidence of the sun,

FIG. 1d shows a diagram depicting the changing angle of incidence,

FIG. 1e shows a diagrammatic view depicting a longitudinal section through the collector on FIG. 1a,

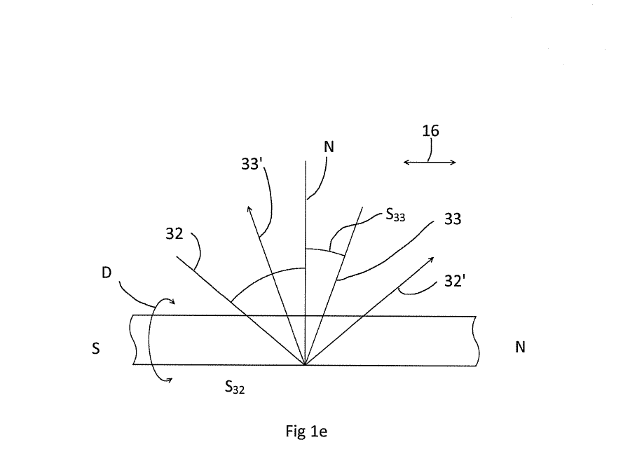

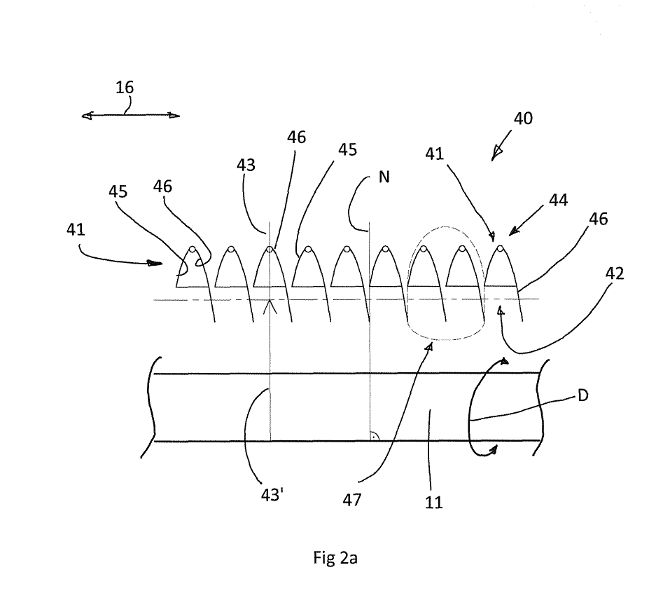

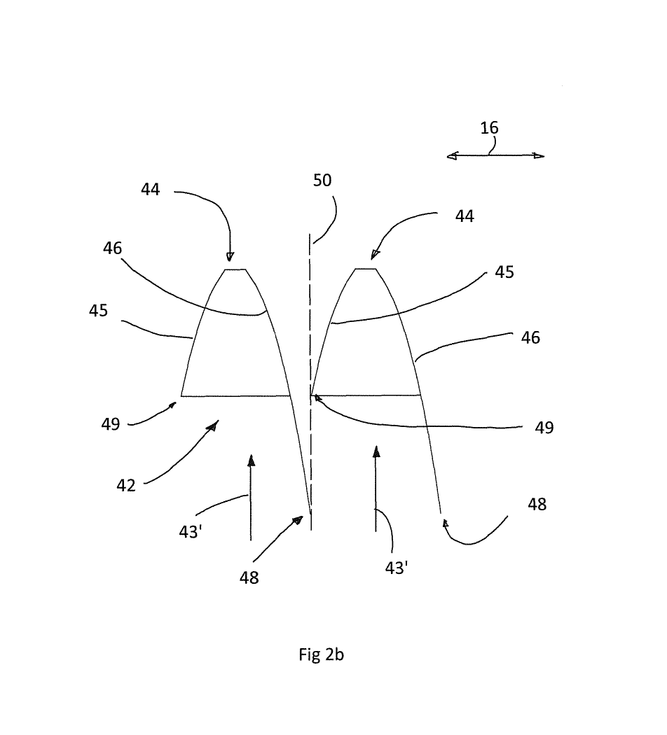

FIG. 2a shows a snippet of the longitudinal section through a trough collector according to the invention,

FIG. 2b shows a magnified view of the dashed area on FIG. 2a,

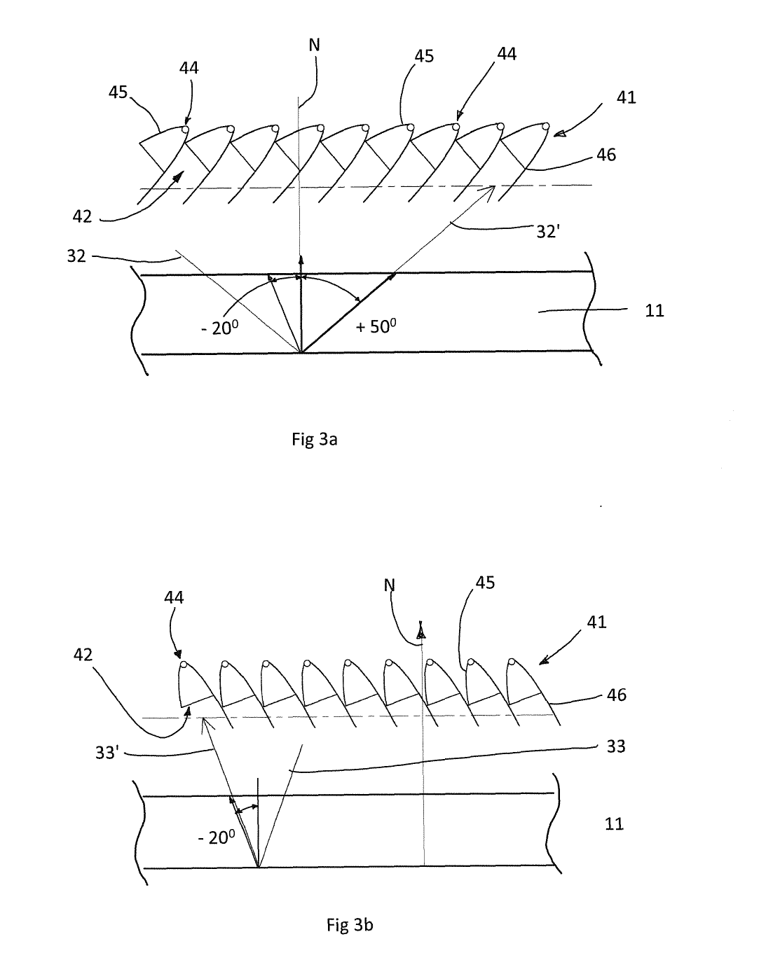

FIG. 3a shows the snippet on FIG. 2a with the secondary concentrators in another pivoting position based on the angle of incidence S of the solar radiation,

FIG. 3b shows the snippet on FIG. 2a with the secondary concentrators in a further pivoting position based on the angle of incidence S of the solar radiation,

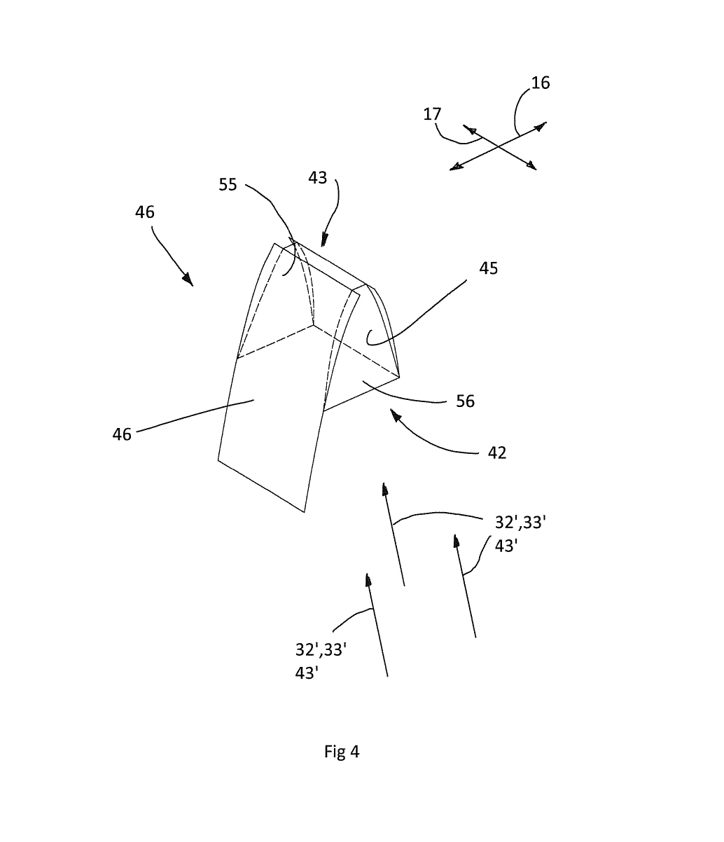

FIG. 4 shows a three-dimensional view of a preferred embodiment of the primary concentrator according to the invention,

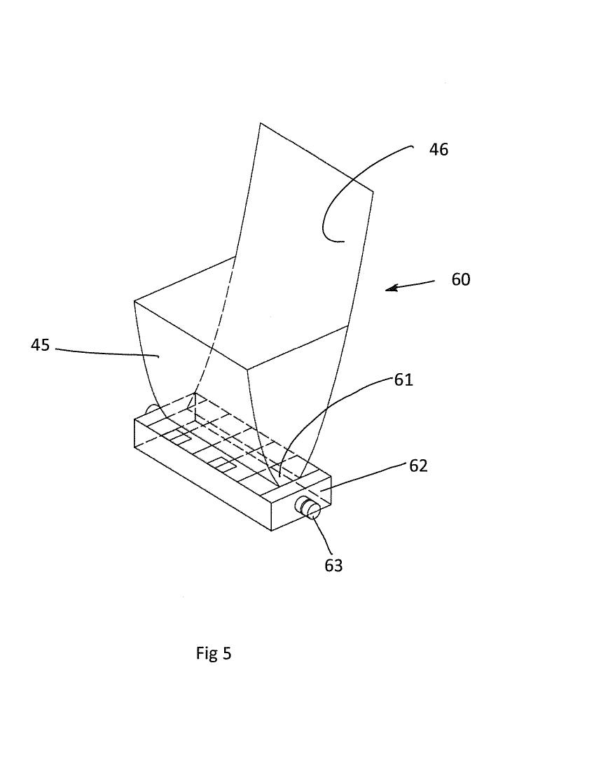

FIG. 5 shows a three-dimensional view of a further preferred embodiment of the primary concentrator according to the invention with an allocated photocell,

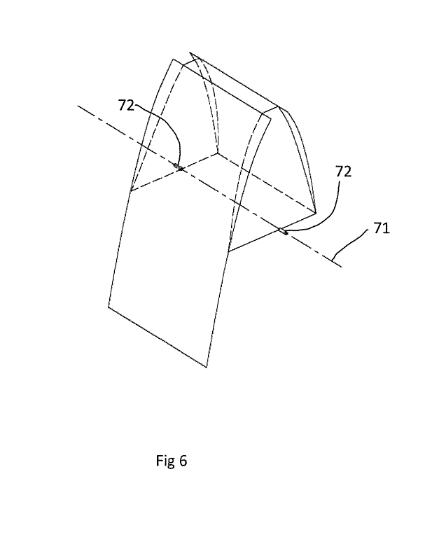

FIG. 6 shows a three-dimensional view of a further preferred embodiment of the primary concentrator according to the invention with a pivoting device for pivoting relative to the primary concentrator, and

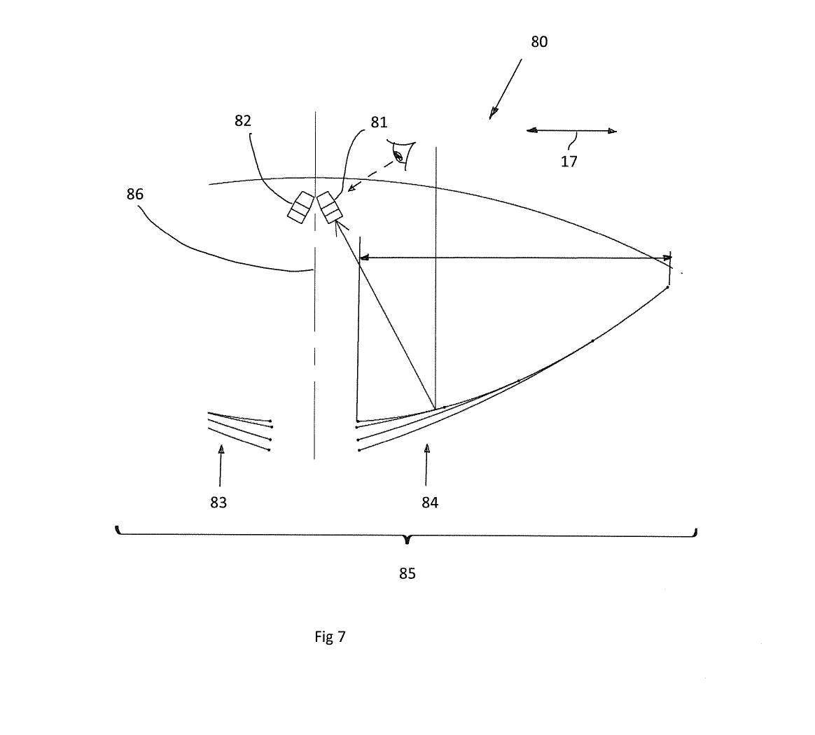

FIG. 7 shows a cross section through a pressure cell of a trough collector according to the invention with secondary concentrators, which are allocated to a respective longitudinal section of the primary concentrator.

FIG. 1a shows a conventional trough collector 1 with a pressure cell 2, which exhibits the shape of a cushion, and is formed by an upper, flexible membrane 3 and a lower, flexible membrane 4 that is not visible on the figure.

The membrane 3 is permeable to sunrays 5, which strike a concentrator membrane (concentrator 10, FIG. 2a) inside the pressure cell 2, and are reflected by the latter as rays 6 to an absorber pipe 7, in which circulates a heat-transporting medium that dissipates heat concentrated by the collector. The absorber pipe 7 is held by a brace 8 in the focal line area of the concentrator membrane (concentrator 10, FIG. 2a).

The pressure cell 2 is mounted in a frame 9, which in turn is secured to a rack so that it can pivot based on the daily position of the sun.

Such solar collectors are described in WO 2010/037243 and WO 2008/037108, for example. These documents are expressly incorporated into the present specification by reference.

Even though the present invention preferably finds application in a solar collector of this type designed as a trough collector, i.e., with a pressure cell and a concentrator membrane mounted in the pressure cell, it is by no means limited thereto, but can rather likewise be used in trough collectors whose concentrators are not designed as flexible mirrors, for example. For example, collectors with inflexible mirrors are used in the power plants mentioned above.

In like manner, photovoltaic cells can be provided in place of an absorber pipe.

The respective parts of the trough collector not relevant to understanding the invention have been omitted from the figures described below; let it be noted here once again that these omitted parts are designed in accordance with the prior art described above (collectors with pressure cell or those with inflexible mirrors), and can be easily determined by the expert for the specific application.

FIG. 1b shows a trough collector with secondary concentrators. A collector 10 basically designed like the collector 1 on FIG. 1a exhibits a concentrator 11 and an absorber pipe 12 secured to a brace 8. The sunrays 5 hit the primary concentrator 11, and are reflected by the latter as rays 6. The specific design of the concentrator 11 yields a radiation path for reflected radiation represented by the rays 6.

With respect to the orientation on the figure, arrow 16 denotes the longitudinal direction, and arrow 17 the transverse direction. Accordingly, the concentrator 11 is curved in the transverse direction 17, and concentrated in a first direction, namely in transverse direction 17.

The radiation path of the concentrator 11 necessarily exhibits a focal line area or a focal plane, since the incident radiation 5 from the sun is not parallel due to its opening angle, so that concentration in a geometrically precise focal line is not even possible at all, and additionally because the concentrator cannot be given a precisely parabolic curvature for a focal line theoretically approximated to the greatest extent possible with a reasonable cost outlay.

The optical elements 20 with a plate-like design on the figure transparent to concentrated radiation constitute part of a secondary concentrator, and are situated in the first radiation path of the concentrator 11, so that the radiation path runs through the latter. These optical elements 20 diffract the incident radiation 6 (reflected by the concentrator 11) in a second direction, namely in the longitudinal direction 16, in such a way as to concentrate the radiation 6 in focal point areas 21 after the optical elements 20. The figure depicts a number of optical elements 20 (and hence secondary concentrators) corresponding to the length of the solar collector, recording their focal point areas for an example of two optical elements 20.

For example, the secondary concentrators here also include carriers 22, which are secured to the absorber pipe 12, and on which the optical elements 20 are held in position.

The absorber element here designed as an absorber pipe 12 is in the location of the focal point areas 21, and has a number of thermal openings 23 through which the concentrated radiation 15 passes into the absorber pipe 12. A thermal opening allows the transfer of heat from the concentrated radiation, but is not necessarily designed as a mechanical opening.

Photovoltaic cells can also be provided at the location of the thermal openings 23.

FIG. 1c diagrammatically shows the position of the primary concentrator 11 aligned in the north-south direction relative to the sun, which traces its path 30 from morning to evening. According to the view on FIG. 1c, the concentrator 11 is tilted to the left in the morning, i.e., eastward, and to the right in the evening, i.e., westward (the corresponding pivoting motion by the concentrator 11 is denoted by the double arrow D recorded on the figure). Depending on location and season, the sun traces a higher or lower path 30 across the sky, so that a sunray 31 hits the concentrator 11 aligned to the sun at an inclination. The angle of incidence S between the sunray 31 and normal N on the concentrator 11 is known as the skew angle S. The normal N is perpendicular on the lowest surface line of the concentrator 11.

FIG. 1d presents a diagram that horizontally depicts the time of day (morning—afternoon—evening) and an accompanying skew angle (angle S). The skew angle or angle of incidence S usually lies between 20° and 50° in the winter (curve A), and between minus 20° and plus 70° in the summer (curve B). It thus becomes necessary to correspondingly arrange the secondary concentrators so as to allow them to be pivoted synchronously to each other in the trough collector, so that they can be aligned based on the incident radiation 31 during the day as the position of the sun changes.

FIG. 1e shows a longitudinal section through the concentrator 11 with a view of its eastern half. A sunray 32 is depicted striking the concentrator 11 at a skew angle S of approx. 50°, and being reflected as a reflected ray 32′ at the same angle to the normal N. Further shown is second sunray 33 that is incident at a skew angle S of approx. minus 20° and reflected as a ray 33′. For example, rays 32′ and 33′ border the pivoting range required for optimized secondary concentrators.

FIG. 2a diagrammatically shows a longitudinal section through a trough collector 40 according to the invention, e.g., corresponding to a collector according to FIGS. 1a and 1b, wherein only a cutout from the middle of the collector 40 is shown with its ends omitted in order to simplify the figure.

In place of the absorber pipe 12 (FIG. 1b), the invention provides secondary concentrators 41 with a photovoltaic element, with an inlet area 42 and outlet area 43. The incident sunrays 43 are concentrated in a transverse direction 17 by the concentrator 11, and in the inlet area 42 make their way as reflected sunrays 43′ into the respective secondary concentrator 41, which in turn concentrates the sunrays 43′ once again in the longitudinal direction 16, so that a focal point area arises in its outlet area 44 for what is now once longitudinally and once transversely concentrated solar radiation.

For purposes of concentration in the longitudinal direction 16, each secondary concentrator 41 has a first reflecting wall 45 and a second reflecting wall 46 for the radiation 42′ incident therein. According to the invention, the first and second reflecting wall 45, of the secondary concentrators 41 exhibit a different length in the inlet area 42 for the radiation, such that a longer reflecting wall of one secondary concentrator lies next to a respective shorter reflecting wall of the adjacent secondary concentrator.

FIG. 2b presents a magnified view of a cutout according to the dashed area 47 on FIG. 2a.

Two adjacent secondary concentrators 41 are shown, both aligned parallel to the normal N (FIG. 2a). As further evident, the second wall 46 is here longer than the first wall 45, wherein the gap between the secondary concentrators is dimensioned so that the lower edge 48 of the longer wall 46 casts a shadow on the lower edge 49 of the shorter wall 45 when the reflected radiation 42′ is also incident in the secondary concentrators 41 parallel to the normal N. This is illustrated by the dashed line 50. As a result, no gap arises for the radiation 43′ reflected by the concentrator 11 between the secondary concentrators 41. The latter are hence designed and arranged to completely detect the radiation reflected by the concentrator over the entire pivoting range during operation.

FIG. 3a now shows the system according to the invention, namely a concentrator 11 with secondary concentrators 41 allocated thereto given incident sunrays 32 at a skew angle S of 50°. The secondary concentrators are pivoted to reflect this angle. The longer walls 46 project into the inlet areas 42 of the adjacent secondary concentrators 41. In other words, the shorter walls 45 make space available for the longer walls 46, thereby making it possible to pivot the secondary concentrators 41 in the first place. Even in this pivoting position, there is no gap between the secondary concentrators 41 for reflected radiation 32′, so that the latter again detect all rays reflected by the concentrator 11.

FIG. 3b depicts the system according to the invention at a skew angle S of minus 20°. The longer walls 46 of the secondary concentrators 41 each hit a shorter wall 45 of an adjacent secondary concentrator 41, limiting the pivoting range to a skew angle S of minus 20°, which in turn is sufficient according to the expected angles of incidence S (see FIG. 1d). Even in this pivoting position, there is no gap between the secondary concentrators 41 for reflected radiation 33′, so that the latter again detect all rays reflected by the concentrator 11.

FIG. 4 presents a three-dimensional view of a secondary concentrator 41 according to the invention with its first longer wall 46, the second shorter wall 45 and two side walls 55 and 56.

In a preferred embodiment, the first shorter 45 and second longer 46 reflecting wall of the secondary concentrator are designed as a compound parabolic concentrator, which is known to the expert as such. A compound parabolic concentrator has an acceptance angle AW at which radiation incident at this angle Θᵢₙ is only reflected once on a wall 45, 46, and then emitted from the outlet area 43 at an angle Θₒᵤₜ. It is preferred that the shorter wall 45 and longer wall each exhibit the same value for Θᵢₙ and Θₒᵤₜ, i.e., that the profile of the shorter wall 45 match the longer wall 46, from which the corresponding section was cut away.

In a specific case, the expert can now configure the secondary concentrator according to the invention in such a way that the desired secondary concentration comes about in the longitudinal direction on the one hand, and that the difference in the length of the two longitudinally concentrating walls ensures the specifically necessary level of pivoting capability on the other.

Let it be noted in particular that the opening angle of the sun Θᵢₙ must measure at least 0.5°. Deviations of the concentrator from the ideal parabolic shape lead to errors in the ideal concentration, so that Θᵢₙ preferably leis between 5° and 10°. The expert can select a suitable value for θₒᵤₜ, which among other things is tailored to a photocell arranged by the outlet area 43 or thermal opening of an absorber pipe.

In another embodiment, the secondary concentrators 41 exhibit means for further concentrating the incident radiation in the first, transverse direction 17 (FIGS. 1a and 1c). Preferably provided for this purpose is a third reflecting wall 55 and fourth reflecting wall 56, which lie opposite each other and are designed as a hyperbolic concentrator. According to the invention, the third wall 55 and fourth wall 56 can also be designed as a wedge concentrator. Both a hyperbolic concentrator and a wedge concentrator are known as such to the expert, who can suitably configure the latter for the specific case.

For example, a concentration of 55 suns can be reached for the primarily concentrated radiation at a width for the primary concentrator 11 of 4.8 mm and an opening angle of 150° by appropriately selecting the width (transverse direction 17) of the inlet area 42 (FIG. 4) of the secondary concentrator 41. If the expert then rates the secondary concentrator 41 for a secondary concentration of 10 in the longitudinal direction 16, an overall concentration of 550 suns is obtained. The latter can be improved even further via transverse concentration (see above).

FIG. 5 shows another preferred embodiment of the secondary concentrators 60 according to the invention, which on their outlet area 43 are each rigidly secured to at least one photovoltaic cell 61, which itself is located in a housing 62, wherein the housing 62 in turn has bearing journals 63 with which it can be mounted so as to pivot relative to the concentrator 11. As a result, the at least one photocell is fixed in place relative to the focal point area generated by the secondary concentrator 60 on the one hand, and a simple suspension bracket is provided for the secondary concentrators 60 even in the trough collector on the other.

In another preferred embodiment, the secondary concentrators 41, 60 are situated relative to the primary concentrator 11 in such a way that the focal line area of the primary concentrator in the vertical position of the secondary concentrators 41, 60 lies above the height of the inlet edge 48 of the longer 46 reflecting walls, which concentrate in the second, longitudinal direction, and at or below the height of the inlet edge 49 of the shorter wall 45. Basically, a secondary concentrator, in particular a secondary concentrator also designed as a compound parabolic concentrator, is arranged in such a way that the focal line area or focal plane of the primary concentrator lies at the lower edge of the reflecting walls. In the present secondary concentrator 41, 60 with an asymmetrical design according to the invention, the longer wall 46 takes the larger percentage of radiation to be concentrated. Accordingly, it must be assumed that the focal plane for optimal concentration must lie at the location of the lower edge 48 of the longer wall 46. However, this was surprisingly found not to be the case, and the focal plane must be situated higher to achieve an optimal efficiency for the trough collector.

In instances where the secondary concentrator also exhibits a transverse concentrator, the focal line area or focal plane of the primary concentrator 11 in the vertical position of the secondary concentrators lies above the height of the inlet edge 48 of the longer wall 46, which concentrates in the second transverse direction 17, and at or below the height of the inlet area of the means for concentrating the radiation in the first direction, i.e., preferably of a hyperbolic or wedge concentrator.

FIG. 6 shows an example for a secondary concentrator 70 that can pivot around a pivot axis 71, which in the vertical position of the secondary concentrator lies at the height of the inlet edge of the shorter wall, which concentrates in the second direction. This is enabled by means here designed as a pivoting journal 72, which can be used to mount the secondary concentrator 70 so as to pivot relative to the primary concentrator 11.

FIG. 7 shows an exemplary cross section through the pressure cell 80 of a trough collector 80 designed according to WO 2010/037243.

In a further aspect of the present invention, several secondary concentrators 81, 82 are provided next to each other in the transverse direction 17, wherein each of the adjacent secondary concentrators 81, 82 receives reflected radiation from an allocated longitudinal section 83, 84 of the primary concentrator 85. To simplify the figure, only the right side of the system is shown in its entirety, and is symmetrical to the left, merely implied side in terms of the axis of symmetry 86. Even though this system would appear relevant for transverse concentration, longitudinal concentration can surprisingly be improved: As a result of the curved surface of the primary concentrator 85, the acceptance angle Θᵢₙ for secondary concentration can be reduced if the width of the primary concentrator detected by the secondary concentrator is smaller. As a general rule, the expert knows that a lower acceptance angle Θᵢₙ leads to a higher concentration, in particular for a compound parabolic concentrator. In the case at hand, this means that the efficiency of the trough collector is further improved by using secondary concentrators adjacent to each other in cross section.

The Applicant has discovered that the acceptance angle for longitudinal concentration can then be kept within the following limits: In the inlet area between 0.5° and 10°, preferably between 3° and 10°, especially preferably between 5° and 10°, most preferably between 4° and 5°, wherein concentrated radiation further preferably exits at an angle of at most 70°. These values depend on the quality of the primary concentrator, and can be reduced to 4° to 5° at the best efficiency of a secondary concentrator in a primary concentrator, for example designed according to FIG. 7.

Since the secondary concentrators lie one in back of the other over the length of the primary concentrator (FIG. 1b) and secondary concentrators according to the invention are then also situated adjacent to each other in the transverse direction 17, the secondary concentrators are arranged in several rows over the length of the primary concentrator, wherein each row of secondary concentrators is aligned to a longitudinal section of the primary concentrator allocated thereto.

Of course, this system can be used not just in a primary concentrator designed as shown on FIG. 7 (i.e., based on the disclosure of WO 2010/037243), but rather in conjunction with trough-shaped primary concentrators of any construction. By contrast, it is especially advantageous in a further embodiment for the longitudinal sections with a different curvature viewed in the transverse direction that are formed in a primary concentrator according to WO 2010/037243 to be provided with separate secondary concentrators for each longitudinal section. In the system with two times four longitudinal sections depicted on FIG. 7, two to eight rows of secondary concentrators could be provided in this way, depending on the configuration of the trough collector according to the invention.

In a preferred embodiment, the primary concentrator thus consists of a number of pressurized films regionally lying one on top of the other, and exhibits areas with different curvature, wherein one or more of these areas form a longitudinal section.

1. A trough collector comprising:
a number of secondary concentrators that take solar radiation concentrated by a primary concentrator of the trough collector in a first direction transverse to a length of the trough collector and concentrate the solar radiation in a second direction running longitudinally thereto;
wherein the number of secondary concentrators each comprise a first, front reflecting wall and a second, rear reflecting wall, which second, rear reflecting wall concentrates the radiation in the second direction; and
wherein the number of secondary concentrators pivot synchronously to one another, each secondary concentrator preferably pivots around a pivot axis fixed relative to the primary concentrator, so that the number of secondary concentrators can always be aligned based on incident radiation as a position of the sun changes; and
wherein the first and second reflecting wall of the number of secondary concentrators in an inlet area of radiation exhibit a different length, such that a longer reflecting wall of one secondary concentrator lies next to a respective shorter reflecting wall of an adjacent secondary concentrator.

2. The trough collector according to claim 1, wherein the first and second reflecting walls of the secondary concentrator are each designed as a compound parabolic concentrator.

3. The trough collector according to claim 1, wherein a pivoting range extends over the vertical into the negative angular range.

4. The trough collector according to claim 1, wherein the number of secondary concentrators comprise means for further concentrating the incident radiation in the first direction.

5. The trough collector according to claim 4, wherein the means for further concentration in the first direction comprise a third reflecting wall and a fourth reflecting wall lying opposite the third reflecting wall, which third and fourth reflecting walls are designed as hyperbolic concentrators.

6. The trough collector according to claim 4, wherein the means for further concentration in the first direction comprise a wedge concentrator.

7. The trough collector according to claim 1, wherein the outlet sides of the number of secondary concentrators are each rigidly secured to at least one photovoltaic cell.

8. The trough collector according to claim 7, wherein the number of secondary concentrators are suspended on the at least one photovoltaic cell, which photovoltaic cell is preferably mounted so that the photovoltaic cell can pivot relative to the concentrator.

9. The trough collector according to claim 1, wherein a focal line area of the concentrator in the vertical position of the secondary concentrators lies above the height of the inlet edge of the longer reflecting walls, which concentrate in the second, longitudinal direction, and at or below the height of the inlet edge of the shorter walls.

10. The trough collector according to claim 4, wherein a focal line area of the concentrator in the vertical position of the secondary concentrators lies above the height of the inlet edge of the longer wall, which concentrates in the second direction, and at or below the height of the inlet area of the means for concentrating the radiation in the first direction.

11. The trough collector according to claim 1, wherein the number of secondary concentrators can each be pivoted around a pivot axis, which pivot axis in the vertical position of the secondary concentrator lies at the height of the inlet edge of the shorter wall, which concentrates in the second direction.

12. A trough collector comprising:
a primary concentrator that concentrates incident solar radiation in a first direction transverse to a length of the trough collector;
secondary concentrators that concentrate the radiation concentrated in the first direction in a second direction, running longitudinally to the primary concentrator, onto photocells;
wherein the secondary concentrators are arranged in several rows over a length of the primary concentrator; and
wherein each row of secondary concentrators is aligned to a longitudinal section of the primary concentrator allocated thereto.

13. The trough collector according to claim 12, wherein the primary concentrator comprises a number of pressurized films regionally lying one on top of another, and comprises areas with different curvature, wherein one or more of the areas with different curvature form a longitudinal section.

14. A secondary concentrator for a trough collector, the secondary concentrator comprising:
two reflecting walls lying opposite each other, which two reflecting walls form a compound parabolic concentrator for radiation entering a space lying between the two reflecting walls;
wherein one reflecting wall of the two reflecting walls is elongated relative to the other reflecting wall of the two reflecting walls in an inlet area, and also continues the profile of the compound parabolic concentrator in a protruding section.

15. The secondary concentrator according to claim 14, wherein at least one photovoltaic cell is situated in an outlet area.

16. The secondary concentrator according to claim 14, wherein the space between the two reflecting walls is laterally bordered by additional reflecting walls, which additional reflecting walls form at least one of a hyperbolic concentrator and a wedge concentrator for the incident radiation, which additional reflecting walls concentrate in a direction transverse to a direction of concentration for the compound parabolic concentrator.

17. The secondary concentrator according to claim 14, comprising means to pivot-mount the secondary concentrator, wherein the pivot axis lies at a height of a shorter wall of the compound parabolic concentrator, and is situated parallel to its lower edge.

18. The secondary concentrator according to claim 17, comprising means to pivot-mount the secondary concentrator, wherein the pivot axis lies at a height of at least one photovoltaic cell.

19. The secondary concentrator according to claim 14, wherein:
the acceptance angle in the inlet area lies between 0.5° and 10°; and
concentrated radiation further preferably exits at an angle of at most 70°.

20. A trough collector comprising:
a number of secondary concentrators that take solar radiation concentrated by a concentrator of the trough collector in a first direction and concentrate the solar radiation in a second direction;
wherein the number of secondary concentrators can pivot synchronously around a fixed pivot axis, so that the number of secondary concentrators can always be aligned based on incident radiation as a position of the sun changes, until the number of secondary concentrators hit each other at an end of a pivoting range;
wherein the pivoting range extends from a positive angular range over the vertical into a negative angular range;
wherein the number of secondary concentrators are designed and arranged to completely detect the solar radiation reflected by the concentrator over the pivoting range during operation.

21. The trough collector according to claim 20, wherein:
the number of secondary concentrators each comprise a first, front reflecting wall and a second, rear reflecting wall, which second, rear reflecting wall concentrates the radiation in the second direction;
the number of secondary concentrators pivot synchronously to one another, each secondary concentrator preferably pivots around a pivot axis fixed relative to the primary concentrator, so that the number of secondary concentrators can always be aligned based on incident radiation as a position of the sun changes; and
the first and second reflecting wall of the number of secondary concentrators in an inlet area of radiation exhibit a different length, such that a longer reflecting wall of one secondary concentrator lies next to a respective shorter reflecting wall of an adjacent secondary concentrator.
